(19) United States
(12) Patent Application Publication
(10) Pub. No.: US 2010/0277201 A1
(43) Pub. Date: Nov. 4, 2010

(54) EMBEDDED DIGITAL IP STRIP CHIP

(76) Inventors: Curt Wortman, San Jose, CA (US); Chong H. Lee, San Ramon, CA (US); Richard G. Cliff, Los Altos, CA (US)

Correspondence Address: MARTINE PENILLA & GENCARELLA, LLP, 710 LAKEWAY DRIVE, SUITE 200, SUNNYVALE, CA, 94085, US

(21) Appl. No.: 12/434,606

(22) Filed: May 1, 2009

(51) Int. Cl. H03K 19/173; G06F 17/50

(52) U.S. Cl. 326/38; 716/6; 716/18

(57) ABSTRACT

An integrated circuit (IC) is provided. The IC includes a first region having an array of programmable logic cells. The IC also includes a second region incorporated into the IC and in communication with the first region. The second region includes standard logic cells and base cells. In one embodiment, the standard logic cells are assembled or interconnected to accommodate known protocols. The base cells include configurable logic to adapt to modifications to emerging communication protocols, which are supported by the base cells. The second region can be embedded in the first region in one embodiment. In another embodiment, the second region is defined around a perimeter of the first region. The configurable logic may be composed of hybrid logic elements that have metal mask programmable interconnections so that as emerging communication protocols evolve and are modified, the IC can be modified to accommodate to the changes in the protocol. In another embodiment, a generic device can be customized by replacing the original function with a completely new function targeting a specific application space, e.g., replacing the original function such as a PCI Express, used for computing based applications, with 40 G/100 G Ethernet and Interlaken, used in wireline applications. A method of designing an integrated circuit is also provided.

### BACKGROUND

Programmable logic devices, such as field programmable gate arrays (FPGA) are typically used as prototype platforms but have been commonly replaced by application specific integrated circuits (ASIC), mainly for reasons of cost and power as the product ramps into high volume. Vendors typically provide for a migration path for customers to prototype in FPGAs and then reduce cost and power by converting the design into a structured ASIC when the design has stabilized. Alternatively, hard macros representing large blocks of digital logic directly inside the FPGA, e.g., PCI-Express 2.0 standard blocks, are embedded into the programmable logic devices once the standard is mature.

In either event, as emerging protocols are being developed to facilitate new high bandwidth applications, there is a need to quickly prototype the functionality and release a viable product into the market. Time-to-market is crucial for product adoption. Cost and power is also a concern for developers to make their product feasible for mass production. Emerging protocols have not matured to the required level of stability and there is high risk of having to make additional significant changes after committing to a design when proceeding directly to standard cell implementation. Thus, both the migration path and embedding hard macros have shortcomings with respect to emerging protocols because of the tension between the need for certainty in order to migrate or provide hard macros and the requirement for flexibility as the emerging protocol is developed.

It is in this context that embodiments of the invention arise.

### SUMMARY

Embodiments of the present invention provide circuits and methods for an integrated circuit having a hybrid platform that accommodates the flexibility required by emerging protocols, yet minimizes area and power requirements for the accommodation of the emerging protocol. It should be appreciated that the present invention can be implemented in numerous ways, such as a process, an apparatus, a system, a device or a method on a computer readable medium. Several inventive embodiments of the present invention are described below.

In one embodiment, an integrated circuit (IC) is provided. The IC includes a core region having an array of programmable logic cells. The IC also includes a digital strip incorporated into the IC and in communication with the core region. The digital strip includes standard logic cells and base cells. In one embodiment, the standard logic cells are assembled or interconnected to accommodate known or mature protocols. The base cells are composed of configurable logic cells to adapt to modifications to emerging communication protocols, which are supported by the base cells. The digital strip can be embedded in the core region in one embodiment. In another embodiment, the digital strip is defined around a perimeter (or a portion of the perimeter) of the core region. The configurable logic cells may be composed of hybrid logic elements that have modifiable interconnections that may require metal layer changes to the routing structure. Thus, as emerging communication protocols evolve and are modified, the IC can be modified to accommodate to the changes in the protocol. In one embodiment, the base layers of the digital IP strip are similar to a gate array and therefore are not touched during a metal layer re-spin. In this embodiment, the digital strip is layered upon gate array technology by adding a few metal layers to build logic cells that include multiple simple function cells. It should be appreciated that the simple functions cells can be configured through minimal metal layer programmability to build complex functions. Accordingly, the digital strip logic cells can potentially support multiple independent functions by stitching together simple function cells. In turn, protocol changes can be accommodated through routing changes programmed into the IC. It should be noted that the modifiable interconnections may be referred to as programmable interconnections, in that a specific set of cells are bypassed and the corresponding function of the bypassed cells is replaced by an implementation in the FPGA core region, or alternatively a secondary implementation in the structured ASIC cells. In one embodiment, the hybrid logic elements consume less area than the programmable logic elements of a field programmable gate array because of fixed routing between cells and hard wired functions of the cell function.

In another embodiment, a method for designing an integrated circuit (IC) is provided. The method includes performing a timing analysis on a generated design of the IC and identifying a critical timing path for the generated design. Programmable logic cells along the critical timing path are replaced in the design. The programmable logic cells from the core region of the IC are replaced with standard cells located within the digital strip, which is separate from the core region. The digital strip includes base cells that may be referred to as hybrid logic elements. Within the digital strip there may be heterogeneous regions consisting of a mixture of hybrid logic elements (base cells) and standard cells and homogeneous regions of just hybrid logic elements (base cells) or standard cells. The embodiments described herein endeavor to make the digital strip as homogeneous as possible for the hybrid logic elements to allow the most flexibility. In one embodiment, the hybrid logic element could be built upon a gate array where the digital strip cell may be stripped down to the base layers and replaced with smaller gate array cells. For example, the digital strip may have two programmable metal layers and the gate array may have four layers of metal for both routing and transistor configuration in the cell function. The design of the IC is re-generated with the standard cells disposed within a digital IP strip. The digital IP strip interfaces with the core region of the IC. In one embodiment, the re-generated design may be stored for production of an actual IC. In another embodiment, hybrid logic elements are substituted for the programmable logic elements of the previous design. The hybrid logic elements are located within a digital strip region that is defined separately from the core region. The hybrid logic elements consume less area and metallization layers for the IC, but are configurable to support modifications to any emerging communication protocols. In one embodiment, there could be potentially three iterations of the design where first a hybrid logic element (course iteration) is defined, followed by gate array cell (medium iteration), and then followed by a standard cell (fine iteration).

Other aspects of the invention will become apparent from the following detailed description, taken in conjunction with the accompanying drawings, illustrating by way of example the principles of the invention.

### BRIEF DESCRIPTION OF THE DRAWINGS

The invention may best be understood by reference to the following description taken in conjunction with the accompanying drawings.

FIG. 1 is a simplified schematic diagram illustrating a high level overview of the architecture of an integrated circuit having the digital strip region in accordance with one embodiment of the invention.

FIG. 2 is a simplified schematic diagram illustrating a portion of the integrated circuit providing further details on the components within the different regions of the integrated circuit of FIG. 1 in accordance with one embodiment of the invention.

FIG. 3 is a simplified schematic diagram illustrating the structure of a hybrid logic element utilized for the cells of the digital strip region in accordance with one embodiment of the invention.

FIG. 4 illustrates an exemplary wireline data processing flow through a programmable logic device.

FIG. 5 is a simplified schematic diagram illustrating a hybrid wide data flow structure utilizing logic within the digital strip region in accordance with one embodiment of the invention.

FIGS. 6A-B illustrate the inclusion of interface logic into a digital strip region in accordance with one embodiment of the invention.

FIG. 7 is a simplified schematic diagram illustrating a flow chart for manufacturing an integrated circuit with the digital strip region as described herein in accordance with one embodiment of the invention.

### DETAILED DESCRIPTION

An integrated circuit having a digital strip region is provided. It will be obvious, however, to one skilled in the art, that the present invention may be practiced without some or all of these specific details. In other instances, well known process operations have not been described in detail in order not to unnecessarily obscure the present invention.

The embodiments described herein provide for an integrated circuit having a hybrid platform. In one embodiment, the integrated circuit has a programmable logic device (PLD) core region, such as a field programmable gate array (FPGA) core region, and a digital Intellectual Property (IP) strip or block, which may also be referred to as a structured application specific integrated circuit (ASIC) strip or array. The digital strip includes base cells whose digital functionality can be modified with a limited number of metal masks and standard cell macros that accommodate mature functions/protocols. In one embodiment, the digital strip resides between the analog block and the FPGA core region. In another embodiment, the digital strip is incorporated into or embedded within the core region to encapsulate timing critical circuits such as memory controllers. As will be explained in more detail below, the digital strip is built as a customizable platform to allow users to migrate proprietary logic functions from the core region into this region with low overhead costs. In one embodiment, the “metal-programmable” technology or digital strip is defined as an array of logic cells with routing options provided in the first one-to-five (1-5 LM) metal layers with metal six and above (6-11 LM) used for global signals including routing, clocks, resets, etc. Accordingly, the logic cells of the digital strip are not field configurable in the sense of the Field Programmable Gate Array, i.e., the logic cells of the digital strip are non-user configurable. However, the logic cells of the digital strip may be metal mask programmable by the owner of the chip, which will incur a non-recurring expense, as one skilled in the art will appreciate.

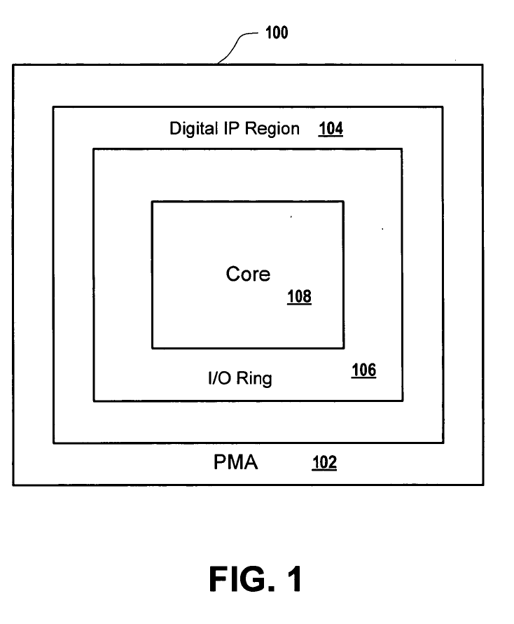

FIG. 1 is a simplified schematic diagram illustrating a high level overview of the architecture of an integrated circuit having the digital strip in accordance with one embodiment of the invention. Integrated circuit 100 includes core region 108, input/output (I/O) region 106, digital intellectual property (IP) strip 104 and physical medium attachment (PMA) region 102. One skilled in the art will appreciate that core region 108 includes the programmable logic elements for a programmable logic device, such as a FPGA, the associated random access memory (RAM), and other blocks typically within the core region of the FPGA. I/O region 106 includes the logic that enables integrated circuit 100 to communicate with various other chips through known standards, e.g., the high speed serial interface (HSSI) standard. Digital IP strip 104 includes the base cells, hybrid logic elements, and standard cells described further below. In one embodiment, digital IP strip 104 contains low-skew high-speed clock networks to drive the data between standard cell macros and the base cell array within the digital IP strip. In another embodiment, multiple clock domains may be utilized within the standard cell macros to isolate the base cell array to support functions, such as lane bonding and rate matching on a per channel basis, at potentially even higher frequencies. One skilled in the art will appreciate that physical medium attachment (PMA) region 102 is an analog/digital interface.

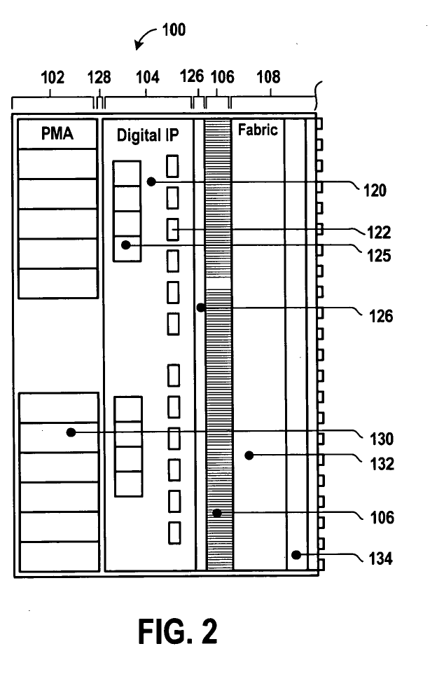

FIG. 2 is a simplified schematic diagram illustrating a portion of the integrated circuit providing further details on the components within the different regions of the integrated circuit of FIG. 1 in accordance with one embodiment of the invention. Integrated circuit 100 includes core region 108, I/O region 106, digital IP strip 104, and PMA region 102. PMA functionality, which is typically implemented in analog circuitry, includes programmable pre-emphasis and equalization, clock data recovery, serializer/de-serializer, and I/O buffers. This functionality is exemplary and not meant to be limiting and may be implemented through PMA channels 130 as one skilled in the art would recognize. Digital IP strip 104 is structured to implement high bandwidth or custom applications with an emphasis on emerging protocols, e.g., protocols that may develop or change. As mentioned above, digital IP strip 104 includes base cells whose digital functionality can be modified with a limited number of metal masks and standard cell macros to accelerate and shrink mature functions. Thus, digital IP strip enables configurable protocol support. For example, with respect to high-speed, multi-lane emerging communication protocols, such as JESD204A, Hypertransport v3.1, SFI-S, etc., or single lane emerging protocols, such as 10 G-SDI, 10 G EPON/GPON, OBSAI v4.0, CPRI v4.0, etc., the logic for accommodating these protocols and any changes as the protocols develop, may reside in digital IP region 104, between PMA region 102 and the core region 108. Alternatively, digital IP strip 104 could also be embedded within the core region 108, to encapsulate timing critical circuits such as memory controllers, processors, and data link layer functions such as media access control (MAC) control functions. The digital IP strip may also include hybrid logic elements (HLE) that can be utilized/interconnected to accommodate the emerging protocols, as described further below. In one embodiment, HLEs from the assignee's HardCopy® family may be used as a coarse cell with a minimum number of metal layers for user routing and “programming/configuration” of the cell function, i.e., one via for programming/configuration, and two metal layers for design specific routing with the one via connecting the two metal layers. Accordingly, the HLE has two pre-built metal layers for defining the cell function in one embodiment. In another embodiment, for medium granularity of a gate array cell it is possible to use 4 metal layers. In this embodiment the cell function is built from one or two layers, depending on the complexity of the function, and two or three layers are used for design specific routing.

In the embodiments described below it should be appreciated that block functions are parameterized and have the option of being enabled or disabled in the data path. Transferring data between digital IP strip 104 and core region 108 may require bonding of two clock networks using a phase compensation first-in first-out (FIFO) buffer, and thus can be considered a common feature to be implemented in standard cell technology. In one embodiment, this implementation may be designed with standard cell technology or built using custom memories to reduce the area and power. Alternatively, a gate array base layer cell configured as a memory bit consuming 12 transistors may be utilized for this feature. In another embodiment, an HLE could be split into two memory bits instead of using a register cell that consumes two HLEs (48 transistors). With the decrease in transistor size, the area consumed by digital functions shrinks, causing regions of unused silicon or areas of only routing that can be utilized for the digital IP strip. As described further below, link-wide functions found in many emerging protocols can be considered candidates for implementation within the digital IP strip discussed herein. Multiple lanes are bonded together for high bandwidth applications requiring complex state machines to coordinate first the individual lane based functions and then link wide functions. Data path convergence points such as link wide cyclic redundancy checks (CRC), scramblers and barrel shifters stress both routing and look up table (LUT) resources of the core region as the computation ripples across the data path width. Accordingly, these link wide functions may be migrated to digital IP strip 104, by incorporating standard cells, base cells and/or HLE into the digital IP strip 104, thereby freeing up the programmable logic elements of the core region. One skilled in the art will appreciate that by reducing the datapath width and removing unnecessary pipeline stages reduces the latency for that function, which is beneficial for functions, such as memory controllers and high performance applications that require low round trip latency, e.g., PCI Express, HyperTransport (HT) and QuickPath Interconnect (QPI).

In digital IP strip 104 of integrated circuit 100, metal mask programmable cells 120 are provided. A number of standard cells 122 within digital IP strip 104 are provided in order to efficiently process data and handle tasks, while maintaining the flexibility through core region 108. For example, standard cells 122 may include the CRC and scrambler functionality referred to above. In addition, physical coding sublayer (PCS) channels 125 may be constructed from a clustered set of standard cells. In essence, digital IP strip 104 commingles standard cells with metal mask programmable cells. Thus, within digital IP strip 104 a heterogeneous mixture of cells reside, e.g., standard cells, hybrid logic elements, and base cells. Digital IP strip 104 supports known communication standards, and is configurable to adapt to emerging communication standards, e.g., communication standards not known or still being developed. Digital IP strip 104 also includes analog/digital interface 128 and FIFO register region 126, which may be referred to as a phase compensation region and functions as a bridge clock structure between core region 108 and digital IP strip 104. Analog/digital interface 128 enables communication between the analog and digital interface, e.g., between regions 102 and 104. Similarly FIFO region 126 enables communication between digital IP strip 104 and the analog components of I/O region 106. Within core region 108, adaptable look-up table modules (ALM) are provided, as well as random access memory blocks 134. One skilled in the art will appreciate that ALM 132 provides user programmable functions, e.g., through a six-input LUT in one embodiment. I/O banks 134 are disposed within region 106.

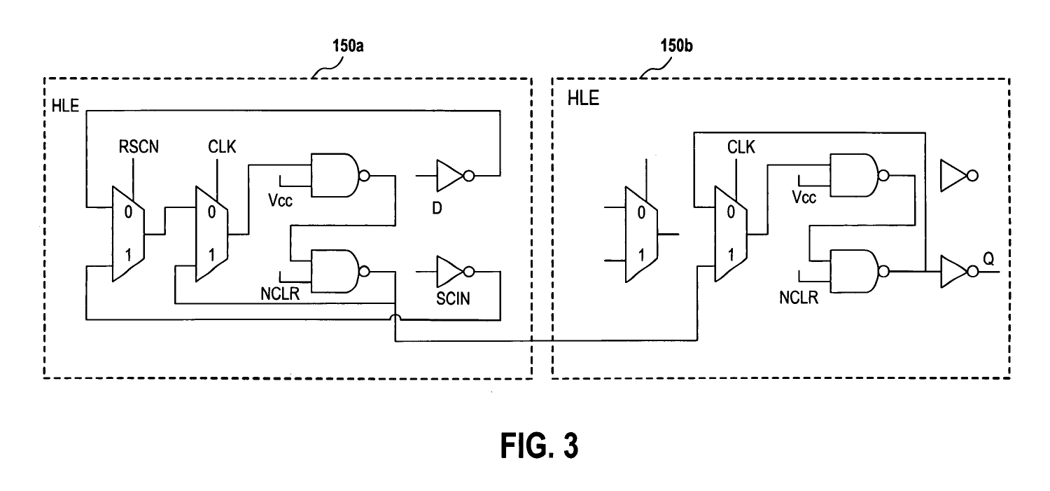

FIG. 3 is a simplified schematic diagram illustrating the structure of a hybrid logic element utilized for digital strip region in accordance with one embodiment of the invention. Hybrid logic elements (HLE) 150a and 150b are illustrated for exemplary purposes and are not meant to be limiting. That is, the hybrid logic elements are not limited to the logic gates illustrated in FIG. 3, as any suitable combination of logic elements may be placed within a hybrid logic element. One skilled in the art will appreciated that repeated pre-built structures such as a gate array or structured ASIC consume more area but uses less metal layers. In addition, with each technology node (i.e. 90 nm to 45 nm) the area decreases such that the amount of digital logic in a given area can quadruple. Contemporaneously, the cost of additional metal layers is increasing dramatically. Programmable logic devices or structured ASICs become more viable since the shrinkage of area is outpacing the demand for complex functions consuming more area. Increased area consumption may relate to increased static power, thus the level of flexibility may be considered for each application.

In one embodiment, the standard cells, represented by HLE 150a and 150b of FIG. 3, contain low level functions that can be configured to build more complex functions. The low level functions are built by predefined metal layers that are interconnected by a minimal number of “programmable” metal layers to form a more complex function. It should be noted that the standard cells of the HLE may be constructed by defining interconnection among base cells in one embodiment. As is apparent to one skilled in the art, the trade off for minimizing metal layers offering greater programmability is that unused low level functions consume area. Therefore decreasing the overall area efficiency is desirable, but this expense is typically less than doing a full metal layer change to fixed digital functionality. The platform having a digital IP strip described herein accommodates many designs and retains the flexibility for adapting to changes in emerging communication protocols by replacing the functionality previously assigned to base cells in the core region with standard cells within the digital IP strip. Further details on the standard cells, hybrid logic elements and base cells may be found in U.S. Pat. No. 7,243,329 and in US Patent Publication 20070210827, both of which are incorporated by reference in their entirety for all purposes.

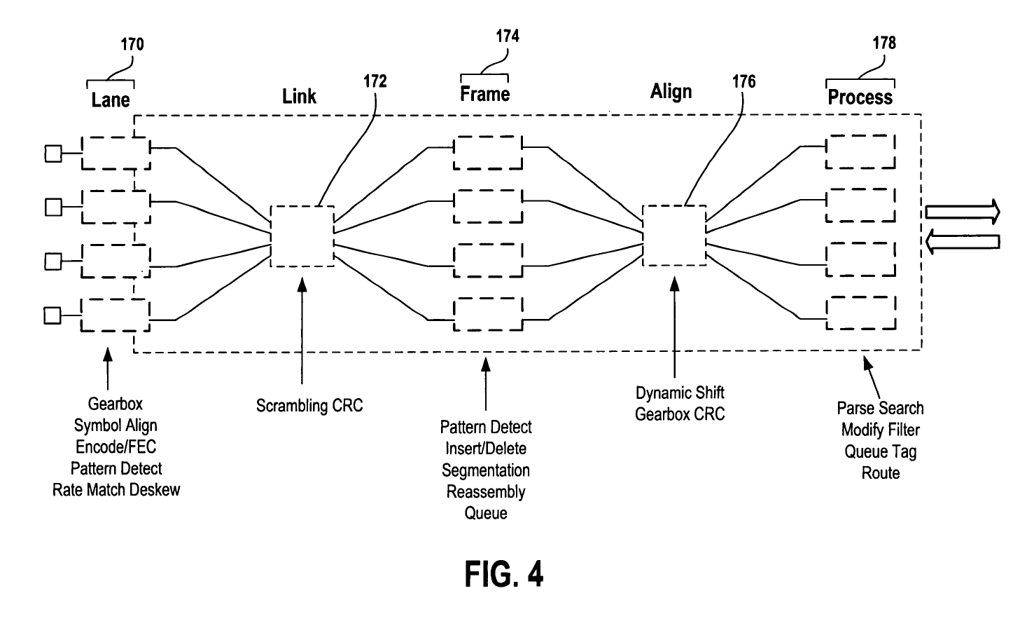

FIG. 4 illustrates a traditional flow through a programmable logic device. A plurality of lanes 170 connect through link 172 and are distributed to frames 174. It should be appreciated that lanes 170 may handle data associated with gearbox, symbol align, encode/forward error correction (FEC), pattern detect, rate match, and de-skew functionality. It should be noted that this list of functionality is exemplary and not meant to be exhaustive. Link 172 represents a bond where multiple lanes are aggregated therethrough. The multiple lanes may be aggregated for scrambling or CRC purposes, in one embodiment. Frame 174 receives the data from link 172 and this data may be associated with pattern detect, insert/delete, segmentation, reassembly, queue, etc. The data from frame 174 is then aggregated again in align link 176. The data may be aggregated for dynamic shift purposes, gearbox, and CRC functionality in exemplary embodiments. The data from align link 176 is then distributed to process nodes 178 where the data can be parsed, searched, modified, filtered, queued, tagged, routed, etc. It should be appreciated that with the expansion of data rates, and where multiple bond lanes are aggregated through a single link, routing congestion occurs through those linked bond lanes. For example, as 32 bit data paths expand to 128 bits, 256 bits, 512 bit data paths, the increased inputs are causing increased interconnect delays at the aggregated congestion areas in the core region.

One skilled in the art will appreciate that the functionality defined for lanes 170, frames 174, and process nodes 178 of FIG. 4 is well suited for programmable logic devices. The embodiments described herein further enhance a programmable logic device for accommodating this functionality, as well as maintaining flexibility for adapting to emerging protocols. Furthermore, the functionality listed with regard to FIG. 4 is exemplary and not meant to be limiting as other functionality typically performed by programmable logic devices may be included.

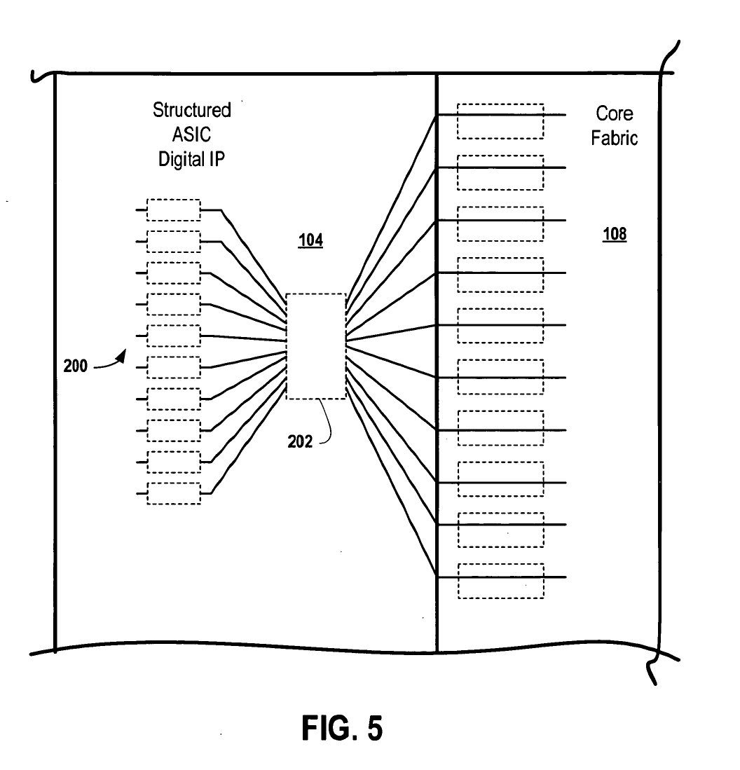

FIG. 5 is a simplified schematic diagram illustrating a hybrid wide data flow structure utilizing logic within the digital IP strip in accordance with one embodiment of the invention. In FIG. 5, data from links 200 are distributed to standard cell 202 within digital IP strip 104. Standard cell 202 can be configured to handle the data rates for a communication protocol, that is either known or emerging, in accordance with one embodiment of the invention. Standard cell 202 can then distribute the data to the core region 108 and the associated destination points within the core region. It should be appreciated that emerging protocols, e.g., protocols that may change over time or unknown protocols, can be accommodated through programming interconnects to configure the standard cells, HLE, and/or base cells of digital IP strip 104 to perform the functionality previously assigned to logic elements of the core region. Thus, the flexibility for a user is maintained. It should be noted that the programming interconnects mentioned herein can be dynamic or static. Dynamic interconnects indicate that a function could be enabled via a multiplexer selection such as the CRC-32 block, or even bypassed if the function is not required for that particular protocol. Static interconnects indicate that the function could be metal layer modified to be a new function, such as CRC-16, assuming the function could fit in that same area.

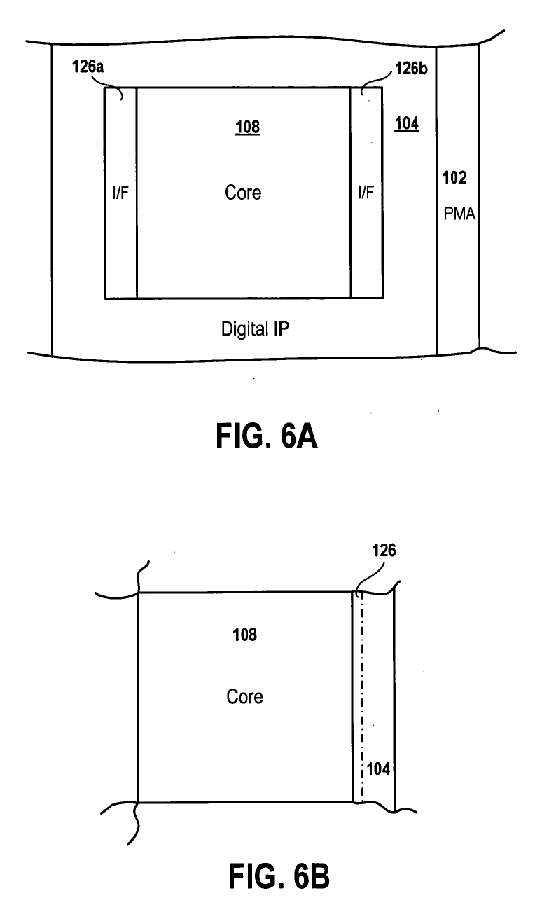

FIGS. 6A-B illustrate an inclusion of interface logic into a digital strip in accordance with one embodiment of the invention. Integrated circuit 220 includes core region 108, digital IP strip 104, and PMA region 102. Within core region 108, interface logic 126a and 126b enable the core region to communicate with external regions of the chip and/or other devices. Interface regions 126a and 126b may be combined within digital IP strip 104 in order to save area within core region 108, as illustrated by region 126 in FIG. 6B. The consolidation of the interface regions within the digital IP strip of integrated circuit 220 frees up area within core region 108, and additionally reduces power consumption. One skilled in the art will appreciate that the overall area savings achieved by integrating the interface logic from the core region to the digital IP region, along with migrating the functionality for known and emerging protocols from the logic cells of the core region to the digital IP region, is significant.

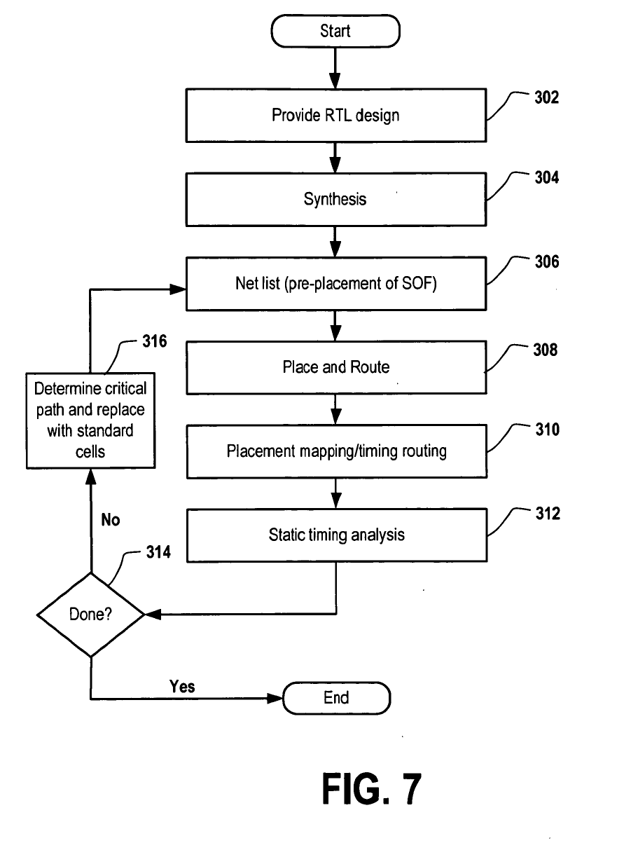

FIG. 7 is a simplified schematic diagram illustrating a flow chart for manufacturing an integrated circuit with the digital IP strip as described herein in accordance with one embodiment of the invention. In operation 302, a register transfer level (RTL) design is provided. A synthesis tool receives the RTL design in operation 304 and synthesis of the design commences. From the synthesis provided by the design compiler in operation 304, a netlist is generated in operation 306. It should be appreciated that the net list in operation 306 provides pre-placement for the netlist of the circuit design. From the netlist, a place and route technique in operation 308 performs initial placement and routing of the cells representing the circuit function. Place and route operation 308 yields timing data in operation 310 for the layout as provided in operation 308.

A static timing analysis is performed in operation 312 of FIG. 7 in order to verify that the signals will be valid during the correct timing windows of the circuit design. In decision operation 314, it is determined if the process is complete. If the process is not complete, the method advances to operation 316 where the critical paths are identified and core logic cells may be replaced with faster cells at the expense of flexibility, such as flexible gate array cells or standard cells assuming the initial netlist contained the most flexible cells (HLEs), in accordance with one embodiment of the invention. In operation 316, the standard cells, HLE, and/or base cells are incorporated into one of the customized layers of the chip. The method then returns to operation 308 and repeats as described above. It should be appreciated that once the design is adjusted, i.e., core logic cells are replaced with standard cells, HLE and/or base cells in a digital IP strip, the adjusted design may return to operation 304 instead of operation 308 and repeat as described above in order to generate a final design. In addition, a script identifying the critical paths may be integrated into operations 304 or 306 in one embodiment. In another embodiment, the critical path is identified by static timing analysis. In this embodiment, a tool looks at all the paths within the design and determines the delay along the path. The delay is compared against the required maximum delay constraint imposed by the clock period for a synchronous design. The tool, e.g., an Electronic Design Automation tool, identifies all paths that have negative slack that the design must correct by modifying the amount of combinational logic in the path. In one embodiment, the number of cells is reduced by implementing the function differently in the RTL. Depending on whether the area has been identified as homogeneous or heterogeneous, it is determined if it is better to modify the original RTL design or use faster cells along the path to reduce the cell delay. It should be appreciated that having the option of using faster cells requires less manual effort than making RTL changes to the design. In addition, the verification and the process can be automated through scripts using faster cells along the path. It should be noted that this embodiment is not limited to going from slow flexible cells to fast cells (e.g., core logic cells to digital IP strip cells), as moving from faster cells to slower cells can also be accommodated (e.g., digital IP strip to core logic cells). That is, the approach can be from the opposite direction starting from fast cells and replacing them with more flexible cells. Depending on the constraints of the design, power and area might be critical and thus the design may be better suited for fine granularity cells, i.e., standard cells. In one embodiment, hold time issues where the data input changes too quickly after the clock edge, can be resolved by replacement with larger and slower cells providing more flexibility as a side benefit. It should be appreciated that the shortest path typically does not consume a relatively large amount of power. In one embodiment, if the power and area budget are underestimated, the short paths may be replaced with flexible cells until power and area budgets are achieved. Although designers desire to minimize power and area, adding some flexible cells might be a reasonable tradeoff to mitigate risk. One skilled in the art will appreciate that cell libraries containing the set of macros with representative logic function may contain the associated timing, power and area information for each of the individual cells.

Through the embodiments described above, enhancements and errata to an emerging protocol may be implemented with minimal impact as only a few metal masks need to be modified. In addition, increased performance is achieved as the interconnect delay has been reduced. The addition of the digital IP strip enables more functionality to be provided inside the core region of a given device. In one embodiment, the device has reduced power associated due to the reduced die area.

The circuits and methods associated with the digital strip described herein, may be incorporated into any suitable integrated circuit. For example, the method and system may be incorporated into other types of programmable logic devices such as programmable array logic (PAL), programmable logic array (PLA), field-programmable gate array (FPGA), field programmable logic array (FPLA), electrically programmable logic devices (EPLD), electrically erasable programmable logic device (EEPLD), logic cell array (LCA), just to name a few. The programmable logic device may be a part of a data processing system that includes one or more of the following components: a processor, memory; I/O circuitry, and peripheral devices. The data processing system can be used in a wide variety of applications, such as computer networking, data networking, instrumentation, video processing, digital signal processing, or any suitable other application where the advantage of using programmable or re-programmable logic is desirable. The programmable logic device can be used to perform a variety of different logic functions. For example, the programmable logic device can be configured as a processor or controller that works in cooperation with a system processor. The programmable logic device may also be used as an arbiter for arbitrating access to a shared resource in the data processing system. In yet another example, the programmable logic device can be configured as an interface between a processor and one of the other components in the system.

Embodiments of the present invention may be practiced with various computer system configurations including hand-held devices, microprocessor systems, microprocessor-based or programmable consumer electronics, minicomputers, mainframe computers and the like. The invention can also be practiced in distributed computing environments where tasks are performed by remote processing devices that are linked through a wire-based or wireless network. In addition, the embodiments described above may be incorporated into any commercially available electronic design automation (EDA) tool, including the Quartus® EDA tool of the assignee.

With the above embodiments in mind, it should be understood that the invention can employ various computer-implemented operations involving data stored in computer systems. These operations are those requiring physical manipulation of physical quantities. Any of the operations described herein that form part of the invention are useful machine operations. The invention also relates to a device or an apparatus for performing these operations. The apparatus can be specially constructed for the required purpose, or the apparatus can be a general-purpose computer selectively activated or configured by a computer program stored in the computer. In particular, various general-purpose machines can be used with computer programs written in accordance with the teachings herein, or it may be more convenient to construct a more specialized apparatus to perform the required operations.

Although the method operations were described in a specific order, it should be understood that other housekeeping operations may be performed in between operations, or operations may be adjusted so that they occur at slightly different times, or may be distributed in a system which allows the occurrence of the processing operations at various intervals associated with the processing, as long as the processing of the overlay operations are performed in the desired way.

Although the foregoing invention has been described in some detail for purposes of clarity of understanding, it will be apparent that certain changes and modifications can be practiced within the scope of the appended claims. Accordingly, the present embodiments are to be considered as illustrative and not restrictive, and the invention is not to be limited to the details given herein, but may be modified within the scope and equivalents of the appended claims.

What is claimed is:

1. An integrated circuit (IC), the IC comprising:
a first region having user configurable logic cells; and
a second region having non-user configurable logic cells, the second region in communication with the first region, wherein a portion of the non-user configurable logic cells are constructed by defining interconnections between logic cell types common to the first and second regions.

2. The IC of claim 1, wherein the second region is located between an outer perimeter of the first region and an inner perimeter of an analog region.

3. The IC of claim 1, wherein the second region includes a digital to analog interface and a phase compensation interface.

4. The IC of claim 1, wherein the non-user configurable logic cells include standard cells.

5. The IC of claim 1, wherein the non-user configurable logic cells include base cells.

6. The IC of claim 1, wherein the non-user configurable logic cells are assembled to accommodate pre-existing protocols.

7. The IC of claim 1, wherein the user configurable logic cells comprise a field programmable gate array.

8. The IC of claim 1, wherein the non-user configurable logic cells are interconnected combinations of the user configurable logic cells.

9. The IC of claim 1, wherein the non-user configurable logic cells are configured during a manufacturing process.

10. The IC of claim 1, wherein the non-user configurable logic cells are metal mask programmable.

11. A method for designing an integrated circuit (IC), comprising:
performing a timing analysis on a generated design of the IC;
identifying a critical timing path for the generated design;
replacing user configurable logic cells along the critical timing path and within a first region of the IC, with non-user configurable logic cells located within a second region of the IC separate from the first region; and
re-generating the design of the IC.

12. The method of claim 11, wherein the identifying is performed during a synthesis process executed on a register transfer level (RTL) design.

13. The method of claim 11, wherein the replacing results in reducing an amount of die area required for an implementation of the re-generated design.

14. The method of claim 11, further comprising:
incorporating multiple types of non-user configurable logic cells within the second region.

15. The method of claim 11, further comprising:
disposing the second region between the first region and an analog region of the IC.

16. The method of claim 11 further comprising:
providing interconnects for linking multiple non-user configurable logic cells.

17. The method of claim 11, further comprising:
incorporating base cells within the second region; and
providing interconnects for linking multiple base cells.

18. The method of claim 11, further comprising:
replacing non-configurable logic cells within the second region with configurable logic cells within the first region.

19. A computer readable storage medium having program instructions for designing an integrated circuit (IC), comprising:
program instructions for performing a timing analysis on a generated design of the IC;
program instructions for identifying a critical timing path for the generated design;
program instructions for replacing configurable logic cells along the critical timing path and within a first region of the IC with non-configurable logic cells located within a second region of the IC that is separate from the first region;
program instructions for re-generating the design of the IC with the non-configurable logic cells disposed within the second region, the second region interfacing with the first region; and
program instructions for storing the re-generated design for production of an actual IC.

20. The computer readable storage medium of claim 19, wherein the program instructions for identifying are executed during a synthesis process executed on a register transfer level (RTL) design.

21. The computer readable storage medium of claim 19, wherein the program instructions for replacing results in reducing an amount of die area required for the re-generated design.

22. The computer readable storage medium of claim 19, further comprising:
program instructions for incorporating base cells within the second region; and
program instructions for providing interconnects for the base cells within the second region.

23. The computer readable storage medium of claim 19, further comprising:
program instructions for disposing the second region between the first region of the IC and an analog region of the IC.

24. The computer readable storage medium of claim 19 further comprising:
program instructions for providing interconnects for linking multiple non-configurable logic cells.

25. The computer readable storage medium of claim 19, wherein the second region includes a digital to analog interface and a phase compensation interface.
